(19) United States
(12) Patent Application Publication
(10) Pub. No.: US 2007/0284646 A1
(43) Pub. Date: Dec. 13, 2007

(54) NONVOLATILE SEMICONDUCTOR MEMORY DEVICE

(75) Inventors: Shoko Kikuchi, Kawasaki-shi (JP); Naoki Yasuda, Yokohama-shi (JP); Koichi Muraoka, Sagamihara-shi (JP); Yukie Nishikawa, Kawasaki-shi (JP); Hirotaka Nishino, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/690,401

(22) Filed: Mar. 23, 2007

(30) Foreign Application Priority Data
Mar. 24, 2006 (JP) P2006-084188

(51) Int. Cl. H01L 29/788

(52) U.S. Cl. 257/315; 257/E29.3

(57) ABSTRACT

According to an aspect of the invention, a nonvolatile semiconductor memory device includes: a semiconductor layer comprising an n-type semiconductor region; p-type source-drain regions separated from each other within the n-type semiconductor region; a charge storage layer provided on the semiconductor layer and between the p-type source-drain regions, the charge storage layer comprising a high dielectric constant material; and a control gate electrode provided on the charge storage layer and comprising a material selected from n-type Si, a metal-based conductive material, and a p-type semiconductor material including at least one of Si and Ge.

### CROSS-REFERENCE TO RELATED APPLICATION

This application is based on and claims the benefit of priority from the prior Japanese Patent Application No2006-084188, filed on Mar. 24, 2006; the entire contents of which are incorporated herein by reference.

### BACKGROUND

1. Technical Field

The present invention relates to a nonvolatile semiconductor memory device.

2. Related Art

A memory cell of a nonvolatile semiconductor memory device has a structure where a gate insulation film and a control gate electrode are stacked on a semiconductor substrate. In relation to writing/erasure of data into this memory cell, a voltage is applied between the control gate electrode and a substrate, to thus induce flow of a tunnel current. Data are stored by controlling a threshold voltage by presence/absence of electric charges in a gate insulation film.

Of semiconductor memory devices, MONOS memory has a structure (hereinafter abbreviated as an “ONO film”) wherein there are sequentially stacked a tunnel insulation film (a silicon oxide film) which enables, as a gate insulation film, selective passage of electric charges), a charge storage layer (a silicon nitride film), and a blocking insulation film (a silicon oxide film) for blocking flow of an electric current between the charge storage layer and the control gate electrode. A threshold value is changed by electrons being trapped by trap sites locally existing in the nitride film.

In the related-art MONOS memory element, electrons are trapped in the silicon nitride film that serves as the charge storage layer, thereby causing the threshold value to fluctuate subsequently, a leakage current achieved in the state—where the electric charges are retained—and variations in threshold value derived from detrapping of electrons into the film are controlled by regulating the thickness of the silicon oxide films between which the silicon nitride film is sandwiched.

The structure of the related-art MONOS nonvolatile memory cell is described by reference to FIG. 21. FIG. 21 is a schematic cross-sectional view of a related-art nonvolatile semiconductor memory cell. As shown in FIG. 21, a tunnel insulation film 102 formed from a silicon oxide film having a thickness of about 1 nm to 5 nm, a thick silicon nitride film serving as a charge storage layer 103, and a blocking insulation film 104 formed from a silicon oxide film having a thickness of about 3 nm to 5 nm are formed on the surface of a silicon substrate 101 doped with desired impurities. The tunnel insulation film 102, the charge storage layer 103, and the blocking insulation film 104 are collectively called a gate insulation film 106.

A gate electrode 105 formed from polysilicon is stacked on this gate insulation layer A source-drain diffusion layer 109 including a high concentration of n-type conductive impurities and an LDD diffusion layer 107 including a low concentration of n-type impurities are formed on the semiconductor substrate 101. An insulative sidewall 108 is provided along a side portion of the gate electrode 105. A wiring layer, or the like, is formed as necessary.

In relation to such MONOS memory, there can be expected miniaturization of an element which enables a further reduction in electrical film thickness by replacing a portion or all of the ONO film that has hitherto been used as a gate insulation film with a high dielectric constant material. An attempt to realize a low-voltage-driven MONOS memory element provided with a high dielectric constant material is under consideration (see JP-A-2005-268756).

Particularly, a high-dielectric oxide film, such as a hafnium oxide film or an aluminum oxide film, or a mixture thereof has high thermal stability, and exhibits superior consistency with processes for manufacturing a semiconductor element Therefore, the high-dielectric oxide films or a mixture thereof are expected as candidates for materials of the next-generation gate insulation film.

However, when the high dielectric constant material film is applied to a gate insulation film, detrapped electric charges ascribable to imperfections in a high dielectric constant material are actually evaluated to be present in a larger number than those in a silicon oxide film and a silicon nitride film. A fluctuating shift in threshold voltage achieved after writing/deleting operation is great. Standard variations in threshold voltage, which are required by specifications of a device and achieved during writing/deleting operation or retention of electric charges, are not satisfied Sufficient performance cannot be exhibited during writing/deletion, reading, and retention of data into the memory cell.

### SUMMARY

When a high dielectric constant material is introduced into the gate insulation film as mentioned above, there is a problem of great fluctuations appearing in threshold voltage during writing and deletion of data or retention of electric charges.

The present invention has been made in view of the above circumstances and provides a nonvolatile semiconductor memory device. According to an aspect of the invention, there is provided a highly-reliable nonvolatile semiconductor memory device which exhibits sufficient performance during writing/deletion, reading, and retention by preventing fluctuations in the threshold voltage, which would otherwise be caused when electric charges are detrapped in a state where electric charges are retained after writing/deleting operation.

According to an aspect of the invention, there is provided a nonvolatile semiconductor memory device comprising: a semiconductor layer comprising an n-type semiconductor region; p-type source-drain regions separated from each other within then-type semiconductor region; a charge storage layer provided on the semiconductor layer and between the p-type source-drain regions, the charge storage layer comprising a high dielectric constant material; and a control gate electrode provided on the charge storage layer and comprising a material selected from n-type Si, a metal-based conductive material, and a p-type semiconductor material including at least one of Si and Ge.

According to another aspect of the invention, there is provided a nonvolatile semiconductor memory device comprising: a semiconductor layer comprising a p-type semiconductor region; n-type source-drain regions separated from each other within the p-type semiconductor region a charge storage layer provided on the semiconductor layer and between the n-type source-drain regions, the charge storage layer comprising high dielectric constant material; and a control gate electrode provided on the charge storage layer and comprising a material selected from p-type Si, a metal-based conductive material, and a p-type semiconductor material including at least one of Si and Ge.

### BRIEF DESCRIPTION OF THE DRAWINGS

FIG. 1 is an exemplary schematic cross-sectional view of a nonvolatile memory cell according to a first embodiment;

FIG. 2 is an exemplary schematic cross-sectional view of a nonvolatile memory cell according to a second embodiment;

FIG. 3 is an exemplary CV characteristic diagram showing changes in trapping and detrapping levels achieved before and after stress is applied to an MIS capacitor having a structure of n⁺-type polycrystalline silicon/HfAlOx/an n-type silicon substrate;

FIG. 4 is an exemplary characteristic diagram showing time-changes in Vfb shift induced by a detrapping phenomenon in a MOS capacitor having a structure of n₊-type polycrystalline silicon/HfAlOx/an n-type silicon substrate;

FIG. 5 is an exemplary CV characteristic diagram showing changes in trapping and detrapping levels achieved before and after stress is applied to an MIS capacitor having a structure of an electrode/HfAlOx/a p-type silicon substrate when the work function of the gate electrode has been changed [in connection with an Au electrode, and a work function of about 5.1 ev];

FIG. 6 is an exemplary CV characteristic diagram showing changes in trapping and detrapping levels achieved before and after stress is applied to an MIS capacitor having a structure of an electrode/HfAlOx/a p-type silicon substrate when the work function of the gate electrode has been changed [in connection with an Mo electrode, and a work function of about 4.7 ev];

FIG. 7 is an exemplary CV characteristic diagram showing changes in trapping and detrapping levels achieved before and after stress is applied to an MIS capacitor having a structure of an electrode/HfAlOx/a p-type silicon substrate when the work function of the gate electrode has been changed [in connection with an Al electrode, and a work function of about 4.1 ev];

FIG. 8 is an exemplary CV characteristic diagram showing changes in trapping and detrapping levels achieved before and after stress is applied to an MIS capacitor having a structure of an electrode/HfAlOx/a p-type silicon substrate when the work function of the gate electrode has been changed [in connection with n⁺-type polycrystalline silicon, and a work function of about 3.95 ev];

FIG. 9 is an exemplary characteristic diagram showing a relationship between a trapping level and a work function acquired after application of stress to an MIS capacitor having a structure of an electrode/HfAlOx/a p-type silicon substrate;

FIG. 10 is an exemplary characteristic diagram showing time-changes in Vfb shift induced by a detrapping phenomenon in a MIS capacitor having a structure of an electrode/HfAlOx/a p-type silicon substrate, when a structure of n⁺-type polycrystalline silicon/HfAlOx/an n-type silicon substrate has been adopted and a work function of a gate electrode has been changed;

FIG. 11 is an exemplary CV characteristic diagram showing changes in trapping and detrapping levels achieved before and after stress is applied to an MIS capacitor having a structure of p⁺-type polycrystalline silicon/HfAlOx/an n-type silicon substrate;

FIG. 12 is an exemplary characteristic diagram showing time-changes in Vfb shift when compared with the case of a structure of n⁺-type polycrystalline silicon/HfAlOx/an n-type silicon substrate;

FIG. 13 is an exemplary characteristic diagram showing dependence of trapping level on a stress electric field achieved after stress is applied to an MIS capacitor having a structure of p⁺-type polycrystalline silicon/HfAlOx/an n-type silicon substrate;

FIG. 14 is an exemplary characteristic diagram showing dependence of detrapping level on a stress electric field achieved after stress is applied to an MIS capacitor having a structure of p⁺-type polycrystalline silicon/HfAlOx/an n-type silicon substrate;

FIG. 15 is an exemplary schematic cross-sectional view of a nonvolatile memory cell according to a third embodiment;

FIG. 16 is an exemplary schematic cross-sectional view of a nonvolatile memory cell according to a fourth embodiment;

FIG. 17 is an exemplary schematic cross-sectional view of a nonvolatile memory cell according to a fifth embodiment;

FIG. 18 is an exemplary schematic cross-sectional view of a nonvolatile memory cell according to a sixth embodiment;

FIG. 19 is an exemplary schematic cross-sectional view of a nonvolatile memory cell according to a seventh embodiment;

FIG. 20 is an exemplary schematic cross-sectional view of a nonvolatile memory cell according to an eighth embodiment; and

FIG. 21 is a schematic cross-sectional view of a related-art nonvolatile semiconductor memory cell.

### DESCRIPTION OF THE EMBODIMENTS

In a nonvolatile semiconductor memory device, a threshold value is varied by implanting electric charges into a gate insulation film in a memory cell, to thus store data. Therefore, constraints are imposed on threshold voltage of the memory cell, and subsequent fluctuations in the threshold value that has fluctuated after writing/deleting operation is minimized in the state where the electric charges are retained.

In a related-art MONOS memory cell, after a threshold value has been fluctuated by trapping electrons into a silicon nitride film (silicon nitride layer) that serves as a charge storage layer, fluctuations in the threshold value, which would otherwise be induced by detrapping of electric charges into the film in a state where the electric charges are retained, can be reduced by controlling the thickness of a silicon oxide film between which the silicon nitride film is sandwiched.

However, when a high dielectric constant material film is applied to a gate insulation film, detrapped electric charges ascribable to imperfections in a high dielectric constant material are actually evaluated to be present in a number larger than those in a silicon oxide film and a silicon nitride film. A fluctuating shift in threshold voltage achieved after writing/deleting operation is great.

Through assiduous studies, the present inventors have found that, in the case of a memory cell using a gate insulation film formed from a high dielectric constant material, a shift in threshold voltage, which would otherwise arise after writing/deleting operation as a result of detrapping of electric charges in the charge storage layer formed from a high dielectric constant material, can be prevented by appropriate selection of a combination of the conductivity type of substrates where a gate insulation film is sandwiched, the conductivity type of source-drain regions, and the conductivity type of a control gate electrode.

More specifically, the combinations correspond to (1) (2) provided below.

(1) A combination of (an n-type semiconductor region/p-type source-drain regions/a charge storage layer of high dielectric constant material a control gate electrode selected from n-type Si, a metal-based conductive material, and p-type semiconductor materials including at least one of Si and Ge)

(2) A combination of (a p-type semiconductor region/n-type source-drain regions/a charge storage layer of high dielectric constant material/a control gate electrode of a p-type semiconductor layer including at least one of Si and Ge)

As indicated by (1), in the case of the n-type, semiconductor area/the p-type source-drain regions, implantation of positive holes from an inverted layer of the n-type semiconductor region to the charge storage layer occurs as a result of use of the n-type control gate electrode and the metal-based conductive material. Further, implantation of electrons from the control gate electrode to the charge storage layer arises. In short, through simultaneous implantation of positive holes and electrons, positive and negative electric charges are compensated for in the gate insulation film, whereby the net amount of electric charges contributing to trapping/detrapping of electric charges is decreased, and prevention of occurrence of Vfb shift, which would otherwise cause detrapping of electric charges, is considered to become possible. Even when a control gate electrode of p-type semiconductor material including at least one of Si and Ge is used, electrons are implanted from the control gate electrode to the gate insulation layer, and hence an advantage is yielded.

As indicated by (2), in the case of the p-type semiconductor region/the n-type source-drain regions, implantation of positive holes into the charge storage layer occurs as a result of use of the control gate electrode of p-type semiconductor layer including at least one of Si and Ge, whereby positive and negative charges are compensated for, and the net amount of electric charges contributing to trapping/detrapping of electric charges is decreased. Specifically, by simultaneous implantation of positive holes and electrons, prevention of occurrence of Vfb shift, which would otherwise cause detrapping of electric charges, is possible. Particularly, by combination (2), this effect is exhibited during writing operation in a low electric field.

The tunnel insulation layer is a layer which selectively causes the electric charges existing between the substrate and the charge storage layer to pass. The blocking insulation film (blocking insulation layer) is a layer which blocks flow of an electric current between the charge storage layer and the control gate electrode.

### EMBODIMENTS

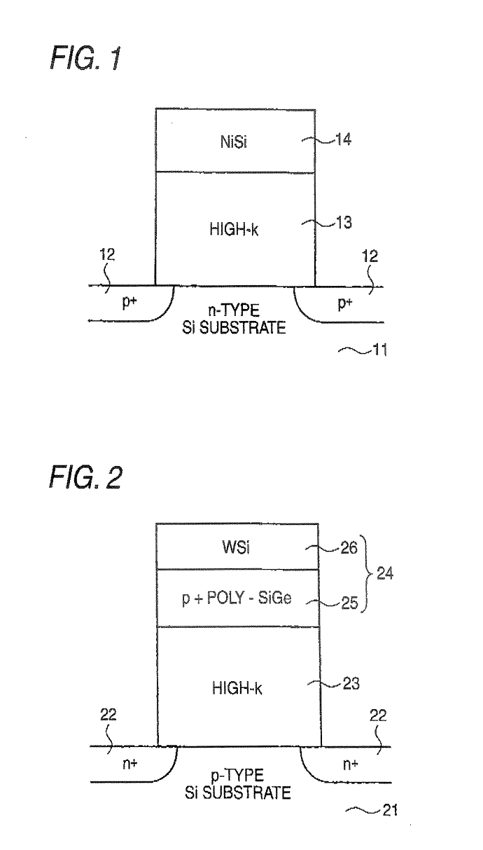

Embodiments will be described hereunder by reference to the drawings while memory cell structure of a NAND nonvolatile semiconductor memory device is taken as an example. The NAND nonvolatile semiconductor memory device comprises bit lines, selection gate transistors used for connecting the bit lines to the memory cells, and a plurality of memory cells which are provided below the transistors and connected in series. FIGS. 1 and 2 are views showing the cross-sectional structure of a memory cell, and the left-side shows a cross-sectional view in the direction of a word line.

### First Embodiment

A schematic cross-sectional configuration of a nonvolatile semiconductor memory cell of the present embodiment will be described by reference to FIG. 1.

As shown in FIG. 1, p-type source-drain regions 12 are formed in an n-type semiconductor area 11 which is formed by doping a silicon substrate with n-type impurities A charge storage layer 13, which is formed from HfAlOx, is between and the source-drain regions 12 on the n-type semiconductor region 11. A nickel silicide layer (an NiSix layer) is formed as a control gate electrode 14 on the charge storage layer 13. NiSix can also be formed into a p-type or an n-type, depending on the nature of impurities used for doping. A work function can also be controlled by controlling a ratio of Ni:Si.

The top surface and side, surface of the laminate are covered with a polarity sidewall oxide film. An interlayer insulation film is formed so as to cover the entire surface of the laminate, Adjacent memory cells are spaced away from each other by an element isolation region of a silicon oxide film.

The structure of the memory cell of the present embodiment corresponds to combination (1); namely, (an n-type semiconductor region/p-type source-drain regions/a charge storage layer of high dielectric constant material/a control gate electrode of a metal-based conductive material).

The thickness of the charge storage layer 13 may range from 1 nm to 30 nm.

In the present embodiment, the control gate electrode 14 facing the gate insulation layer is formed from NiSix. However, in the memory cell comprising combination (1), a metal-based conductive material, such as n⁺-type polycrystalline silicon; at least one element selected from Au, Pt, Co, Be, Ni, Rh, Pd, Te, Re, Mo, Al, Hf, Ta, Mn, Zn, Zr, In, Bi, Ru, W, Ir, Er, La, Ti, and Y; and silicides, borides, nitrides, and carbides thereof, can be used as the material of at least the control gate electrode facing the gate insulation film including the charge storage layer. Further, a p-type electrode may also be used. In this case, electrons are implanted from an inverted layer. One of the electrodes uses Si or SiGe.

In the present embodiment, HfAlOx is used for the charge storage layers 13, 23 of high dielectric constant. In combination (1), a material having a relative dielectric constant of, e.g., 15 to 30, is appropriate as the material of the charge storage layer. Meanwhile, when the relative dielectric constant of the high dielectric constant material is too low, the effect of reducing a leakage current is not yielded. When the relative dielectric constant of the high dielectric constant material is too high, interference arises between the memory cells.

For instance, an oxide, a nitride, and an oxynitride including at least one or more element selected from Al, Hf, La, Y, Ce, Ti, Zr, and Ta can be widely used, or a laminate comprising the films can also be used Particularly, a material employing an Hf or La element as a base material is moderately large in terms of a relative dielectric constant and a barrier height. Further, the material desirably exhibits high thermal stability and low reactivity with respect to a boundary face. Specifically, HfAlO, HfAlON, LaAlO, LaAlON, and the like are the most preferable materials.

(Method for Manufacturing the Cell of the First Embodiment)

HfAlOx, which is to become the charge storage layer 13, is formed on the surface of the silicon substrate 11 that is shown in FIG. 1 and doped with n-type impurities, through use of an ALD method using as materials Al (CH₃)₃, Hf[N(CH₃)₂]₄, H₂O, in aprocess at 250° C. Subsequently, the substrate is annealed at an atmosphere of N₂ under 760 Torr at 1000° C. The charge storage layer 13 of HfAlOx is formed on the silicon substrate 11.

Subsequently, a nickel silicide layer that serves as the control gate electrode 14 is formed by: forming, through sputtering, Ni on the polycrystalline silicon layer formed by CVD; and converting the polycrystalline silicon layer into NiSix in a subsequent heat process.

A resist pattern formed through photolithography processes is sequentially etched into a mask material, the control gate electrode 14, and the charge storage layer 13 through use of the mask material.

Next, the semiconductor region 11 is subjected to ion implantation while the control gate electrode 14 is taken as a mask, to thus form an LDD diffusion layer including a low concentration of p-type impurities.

Next, silicon oxide is deposited by the CVD technique, and etched back to thus form an electrode sidewall oxide film on the side of the control gate electrode 13. A silicon oxide film is removed from the semiconductor substrate by etch-back, whereby the semiconductor substrate is exposed. Subsequently, the substrate is subjected to ion implantation while the gate electrode and the sidewall are taken as masks, whereby the source-drain regions 12 including a high concentration of p-type conductive impurities are formed. Thus, a memory cell is formed. Subsequently, an interlayer insulation film, a wiring layer, and the like are formed by a known method, whereby a nonvolatile memory cell is completed.

The method for forming the charge storage layer, the control gate electrode film, and the like, is not limited to the method described herein. Another source gas may also be used. For instance, there may also be employed a sputtering method, an evaporation method, a laser abrasion method, an MBE method, or a film growth method using a combination thereof other than the ALD method and the CVD method.

### Second Embodiment

The cross-sectional configuration of a nonvolatile semiconductor memory cell according to a second embodiment will be described by reference to FIG. 2. FIG. 2 is a view showing the cross-sectional structure of the memory cell analogous to FIG. 1.

As shown in FIG. 2, n⁺-type source-drain regions 22 are formed in a p-type semiconductor region 21 formed by doping a silicon substrate with p-type impurities. The charge storage layer 23 of HfAlOx is formed between the n⁺-type source-drain regions 22 on the p-type semiconductor region 21. A p⁺-type polycrystalline SiGe layer 25 and a tungsten silicide layer 26 are formed, in this sequence from the charge storage layer 23, thereon as a control gate electrode 24. The work function of the p⁺-type polycrystalline SiGe layer is known to change from 4.6 eV to 5.2 eV according to the concentration of Ge.

In other respects, the memory cell is identical in structure with that of the first embodiment.

The structure of the second embodiment corresponds to combination (2); namely, (i.e., the p-type semiconductor region/the n-type source-drain regions/the charge storage layer of high dielectric constant material/the control gate electrode of p-type semiconductor layer)

The thickness of the charge storage layer 23 may range from 1 nm to 30 nm.

In the second embodiment, the control gate electrode 24 facing the gate insulation layer is formed from a p-type SiGe layer.

In the memory cell of combination (2), p-type Si; e.g., p₊-type polycrystalline silicon, can also be used as a control gate electrode material facing the gate insulation film including at least the charge storage layer. However, p-type SiGe exhibits a high ratio of activation, and may suppress depletion more than p-type silicon does. The band gap of SiGe changes according to the concentration of Ge. Particularly, the concentration of Ge affects the energy level of a valence band. The greater the concentration of Ge, the greater the height of the barrier when viewed from a positive hole. Consequently, the amount of implanted positive holes can be controlled by changing the composition ratio of SiGe.

A layer, which is lower in efficiency than the p-type SiGe layer or the p-type silicon layer, may be used while being stacked on the p-type SiGe layer or the p-type silicon layer. In the present embodiment, tungsten silicide is used. However, full silicides of low resistance other than tungsten silicide, such as nickel silicide, cobalt silicide, and the like, or the metal-based conductive material can be widely used.

Although HfAlOx is used as the charge storage layer 23 of high dielectric constant in the second embodiment, a high dielectric constant material analogous to that used in the memory cell comprising combination (1) can also be used in the memory cell comprising combination (2).

(Method for Manufacturing the Cell of the Second Embodiment)

HfAlOx, which is to become the charge storage layer 23, is formed on the surface of the silicon substrate 21 that is shown in FIG. 2 and doped with n-type impurities, through use of an ALD method using as materials Al (CH₃)₃, Hf[N(CH₃)₂]₄, H₂O, in a process at 250° C. Subsequently, the substrate is annealed in an atmosphere of N₂ under 760 Torr at 1000° C. The charge storage layer 23 of HfAlOx is formed on the silicon substrate 21.

Subsequently, the control gate electrode 24 is formed. The SiGe layer 25 is formed by the CVD technique by use of, as a source gas, Si₂H₆ and GeH₄. The tungsten silicide layer (WSi layer) 26 is formed by forming a polycrystalline silicon layer by the CVD technique; forming W on the polycrystalline silicon by use of W(CO)₆ as a source gas through CVD; and converting the polycrystalline silicon layer into WSix through subsequent heat processes.

As in the case of the first embodiment, a resist pattern formed through photolithography processes is sequentially etched into a mask material, the gate electrode nickel silicide layer 14, and the charge storage layer 13 through use of the mask material.

Next, the silicon substrate 21 is subjected to ion implantation while the control gate electrode 22 is taken as a mask, to thus form an LDD diffusion layer including a low concentration of p-type impurities.

Next, silicon oxide is deposited by the CVD technique, and etched back to thus form an electrode sidewall oxide film on the side of the control gate electrode 24. A silicon oxide film is removed from the semiconductor substrate by etch-back, whereby the semiconductor substrate is exposed. Subsequently, the substrate is subjected to ion implantation while the gate electrode and the sidewall are taken as masks, whereby the source-drain regions 22 including a high concentration of n-type conductive impurities are formed. Thus, a memory cell is formed. Subsequently, an interlayer insulation film, a wiring layer, and the like are formed by a known method, whereby a nonvolatile memory cell is completed.

The methods for forming the charge storage layer, the control gate electrode film, and the like, is not limited to the methods described herein. Another source gas may also be used. For instance, there may also be used a sputtering method, an evaporation method, a laser abrasion method, an MBE method, or a film growth method using a combination thereof other than the ALD method and the CVD method.

<Results of Evaluation Tests>

In order to show working-effects of the memory cells embodied by combinations (1), (2) illustrated in connection with the first and second embodiments, results of element-tests carried out by an MIS capacitor using hafnium aluminate (HfAlOx) are shown.

<1> First, time-dependent changes in the amount of Vfb shift in a three-layer capacitor comprising an n-type substrate/an HfAlOx layer/an n⁺-type polycrystalline silicon layer (hereinafter called a “comparative capacitor”) are studied.

The structure of the comparative capacitor is an alternative structure of a memory cell comprising a combination of (a p-type substrate/n-type source-drain regions/a charge storage layer of an HfAlOx layer/a control gate electrode formed from an n-type semiconductor layer) [this combination is neither combination (1) nor combination (2) and is hereinafter called a “memory cell of comparative structure”].

This comparative capacitor is manufactured by depositing an HfAlOx film having a thickness of about 20 nm on the n⁺-type Si substrate through the ALD method, to thus stack an n⁺-type polycrystalline silicon electrode.

Time-dependent changes in Vfb shift arising after application of stress are examined by use of the comparative capacitor.

Under a method for evaluating the time-dependent changes in Vfb shift, after measurement of an initial CV, an electric field of 15 MV/cm² is applied to the capacitor from the gate side as stress of positive polarity corresponding to that achieved during writing operation for one second. The time-variations in the amount of Vfb shift (ΔVfb) arising after removal of stress is measured with reference to Vfb obtained from the result of CV measurement achieved immediately after application of stress.

Measurement is performed under two conditions; namely, when a low electric field at which recorded data can be retained (3.5 MV/cm) is applied as an electric field applied after removal of stress; and when no electric field is applied. A difference in Vfb existing between an initial CV curve and a CV curve achieved immediately after application of stress is defined as a trapping level. A difference in Vfb existing between a CV curve achieved immediately after application of stress and a CV curve achieved after the capacitor has been left for a given period of time is defined as a detrapping level.

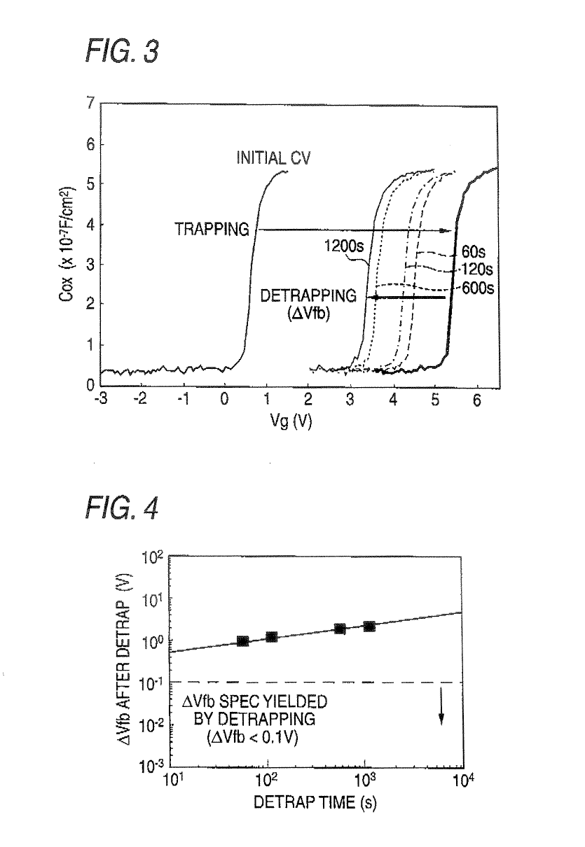

FIG. 3 shows results acquired when a low electric field is applied to the capacitor after removal of stress. As a result of application of stress, the initial CV curve is shifted greatly in the positive direction. Further, after removal of stress, the CV curve is shifted greatly in the negative direction at a given low electric field. The reason for this is that the electrons that have once been trapped as a result of application of stress are considered to be detrapped from the HfAlOx film after removal of stress. The same behavior is observed when no electric field is applied after removal of stress.

Data shown in FIGS. 4 through 8, which are provided as test results hereunder, are data acquired at the time of application of a low electric field which becomes an acceleration test.

FIG. 4 shows chronological changes in the amount of Vfb shift acquired from the CV curve (FIG. 3). From this result, the capacitor exhibits very large variations in Vfb shift and totally fails to fulfill the tolerance of a device; namely, Vfb shift of 0.1V or less (ΔVfb).

From the above result, the memory cell of comparative structure; namely, a combination (a p-type substrate/n-type source-drain regions/a charge storage layer of an HfAlOx layer/a control gate electrode formed from an n-type semiconductor layer), can be a structure where the electric charges are temporarily trapped by the charge storage layer but a shift in threshold voltage becomes greater as a result of detrapping of the electric charges in the state where the electric charges are retained.

<2> Second, time-dependent changes in the amount of Vfb shift in the structure of a three-layer capacitor (hereinafter called “capacitor (1)”) comprising a p-type substrate/an HfAlOx layer/n-type silicon or a metal-based conductive material are studied.

The structure of capacitor (1) is an alternative structure of a memory cell comprising a combination of (an n-type semiconductor substrate/p-type source-drain regions/a charge storage layer of an HfAlOx layer/a control gate electrode formed from n-type Si or a metal-based conductive material) [a memory cell of combination (1)].

Capacitor (1) is manufactured by depositing an HfAlOx film having a thickness of about 20 nm on the p-type Si substrate through the ALD method, to thus additionally stack four types of gate electrode materials.

Time-dependent changes in Vfb shift arising after application of stress to capacitor (1) in the same manner as described in connection with <1> are examined. Specifically, time-dependent changes in Vfb shift are examined by application of a stress electric field of 15 MV/cm of negative polarity, thereby acquiring time-changes in the CV curve and those in the amount of Vfb shift.

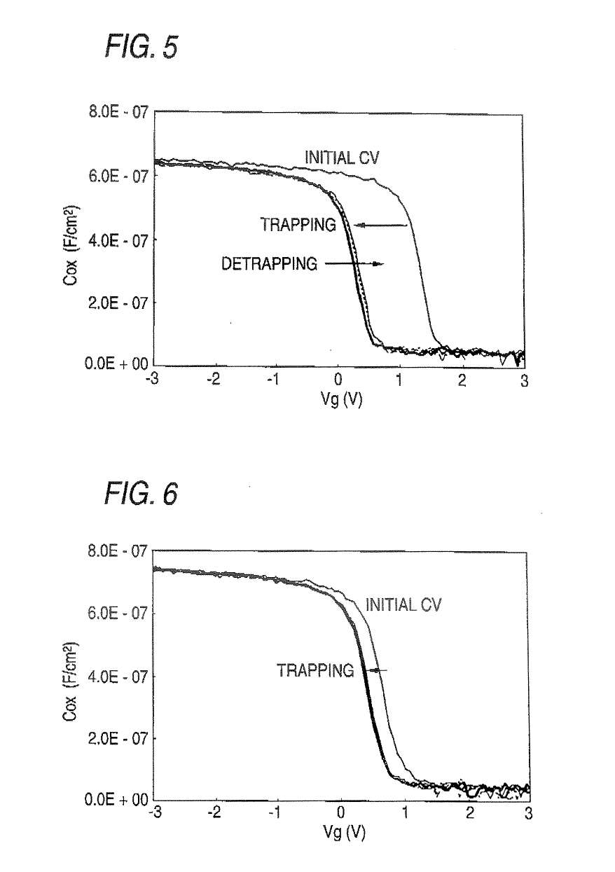

FIGS. 5 to 8 shows CV curves acquired when the following materials are used as the material of the gate electrode namely,

FIG. 5 an Au electrode (a work function of about 5.1 eV)

FIG. 6 an Mo electrode (a work function of about 4.7 eV)

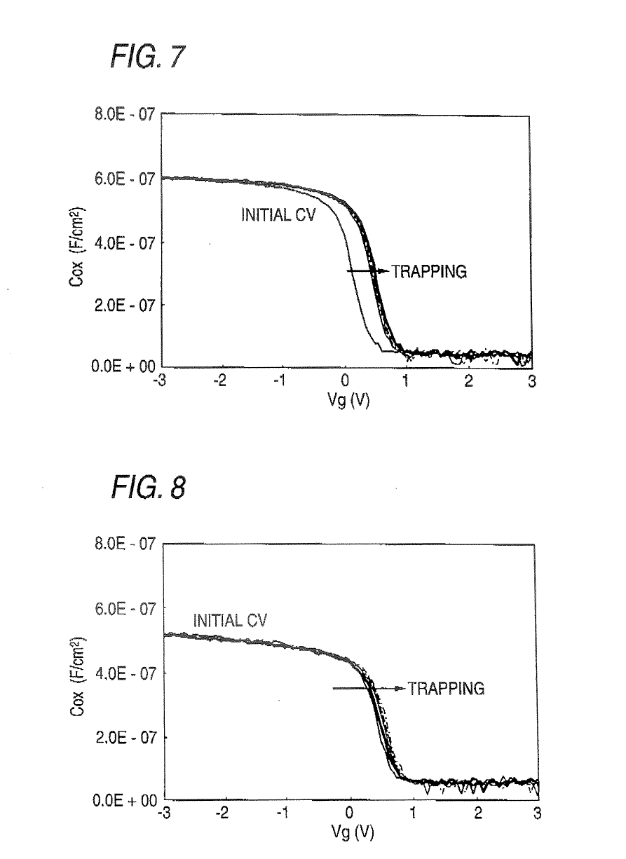

FIG. 7 an Al electrode (a work function of about 4.1 eV)

FIG. 8 an n⁺-type polycrystalline silicon electrode (a work function of about 3.95 eV)

Test results show that a CV shift, which would otherwise be caused by detrapping of electrons, is hardly seen in any of the films regardless of the nature of the electrodes.

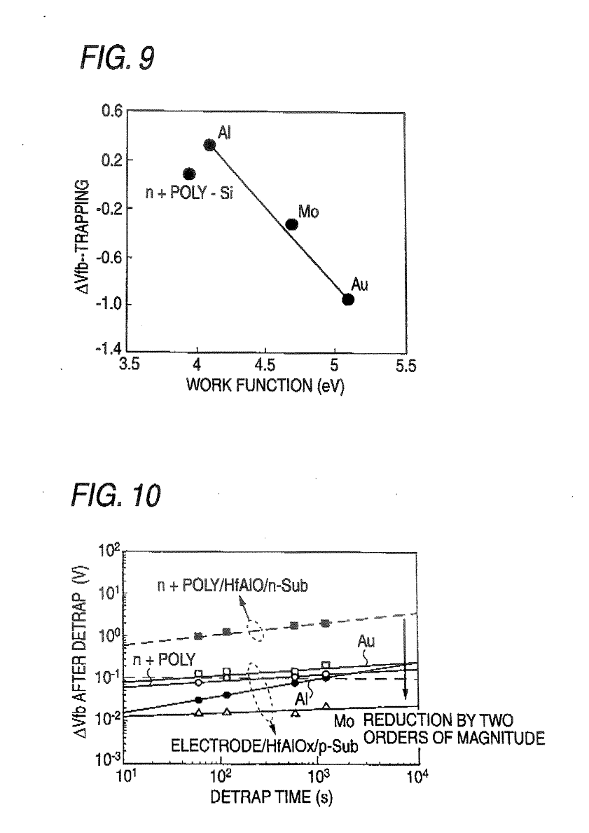

FIG. 9 shows a result of plotting of a relationship between a work function and a trapping level. As shown in FIG. 9, the trapping level is reduced as the work function becomes greater, and dependence of the trapping level on the electrode is ascertained.

Results obtained from the CV curves (FIGS. 5 through 8) and the time-changes in the amount of Vfb shift in the comparative capacitor (FIG. 4) are collectively shown in FIG. 10.

The results show that, in relation to capacitor (2) which has a p-type substrate and enables implantation of holes into the high dielectric constant material film, a detrapping characteristic is seen to be improved by a maximum of about two orders of magnitude when compared with the case of the comparative capacitor. Correlation is seen to exist between the trapping level and the work function of the electrode. As the work function becomes greater, the detrapping characteristic is improved. Implantation of holes resulting from use of the p-type substrate and implantation of electrons induced by the n⁺-type electrode or the metal-based conductive material are performed concurrently, whereby positive and negative electric charges are compensated for. Since the net amount of electric charges contributing to the trapping/detrapping phenomenon has decreased, the detrapping characteristic is considered to be enhanced.

In the previously-described memory cell of combination (1), a structure—which enables concurrent implantation of electrons from a control gate electrode—is realized by application of an n-type semiconductor region/p-type source-drain regions which enable implantation of positive holes from the semiconductor region as well as by application of a control gate electrode of n-type Si or a metal-based conductive material. Thus, occurrence of a Vfb shift, which would induce a trapping/detrapping phenomenon, can be prevented. Since the trapping level can be controlled by controlling a work function, fluctuations in steady threshold value, which arise during writing operation, can be increased by use of a material exhibiting a large work function for a control gate electrode.

<3> Next, time-dependent changes in the amount of Vfb shift in the structure of a three-layer capacitor comprising an n-type Si substrate/an HfAlOx layer/p⁺-type polycrystalline silicon electrode (hereinafter called “capacitor (2)”) are studied.

The structure of capacitor (2) is an alternative structure of a memory cell comprising a combination of (a p-type semiconductor region/n-type source-drain regions/a charge storage layer of high dielectric constant material/a control gate electrode formed from a p-type semiconductor layer including at least Si or Ge) [a memory cell of combination (2)].

Capacitor (2) is manufactured by depositing an HfAlOx film having a thickness of about 20 nm on the n-type Si substrate through the ALD method, to thus additionally stack a p⁺-type polycrystalline silicon electrode (a work function of about 5.05 eV).

Time-dependent changes in Vfb shift arising after application of stress to capacitor (2) in the same manner as described in connection with <1> are examined. At that time, time-dependent changes in Vfb shift are examined by application of a gate voltage of 15 MV/cm of positive polarity, thereby acquiring time-changes in the CV curve and those in the amount of Vfb shift.

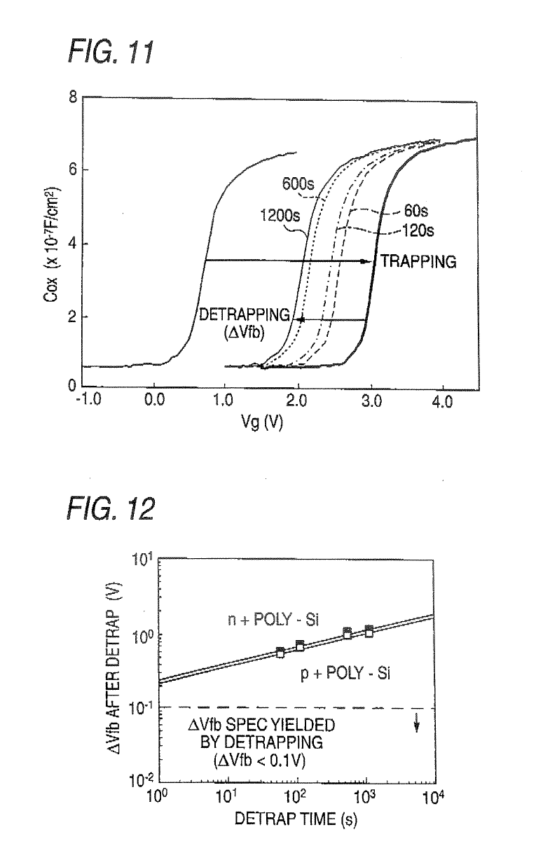

FIG. 11 shows CV curves acquired when a p⁺-type polycrystalline silicon electrode is used. FIG. 12 collectively shows time-changes (depicted by an outlined square) in Vfb shift acquired from the CV curve (FIG. 11) and time-changes in the amount of Vfb shift in the comparative capacitor (depicted by a solid square) (FIG. 4). These results show that the effect of implantation of holes into the p⁺-polycrystalline silicon electrode achieved under conditions of a stress electric field of 15 MV/cm is hardly seen. Therefore, there is examined the dependence of the amount of implanted holes and electrons in a single sample on the magnitude of a stress electric field employed for inducing the trapping/detrapping phenomenon.

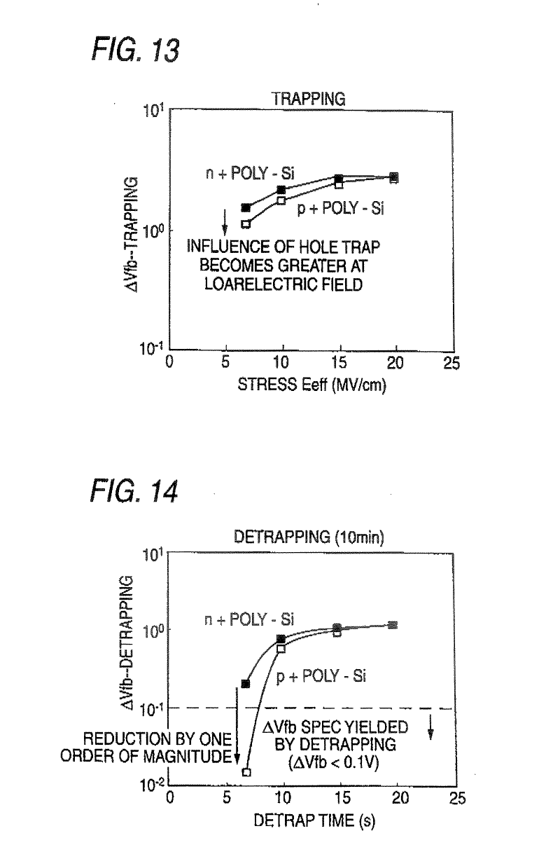

FIG. 13 shows the dependence of a stress electric field on the trapping level achieved when the n⁺-polycrystalline silicon electrode (depicted by a solid square) and the p⁺-type polycrystalline silicon electrode (depicted by an outlined square) are used. The result shows that, as the stress electric field becomes lower, the trapping level in the p⁺-polycrystalline silicon electrode is seen to be decreased as compared with that in the n⁺-type polycrystalline silicon electrode. The reason for this is that the overall trapping level is apparently decreased by the hole traps implanted from the p⁺-type polycrystalline silicon electrode. The effect of a reduction in trapping level is seen to be greater as the electric field becomes smaller.

FIG. 14 shows dependence of a detrapping level on the stress electric field achieved when the n⁺-polycrystalline silicon electrode (depicted by a solid square) and the p⁺-type polycrystalline silicon electrode (depicted by an outlined square) are used. As in the case of the dependence of the trapping level on the stress electric field, the detrapping level in the p⁺-polycrystalline silicon electrode is decreased as the stress electric field becomes lower. Particularly, at a stress electric field of 10 MV/cm or less, the phenomenon is noticeably exhibited. The detrapping characteristic is seen to be improved by an order of magnitude or more when compared with the case of the n⁺-type polycrystalline silicon electrode. Consequently, in the case of capacitor (2) using the n-type Si substrate and the p⁺-type polycrystalline silicon electrode, it has become evident that occurrence of detrapping of electric charges at a low voltage is greatly prevented.

From the above result, in the case of the memory cell of combination (2); namely, when the writing voltage is made low by combination (the p-type semiconductor region/the n-type source-drain regions/the charge storage layer of the HfAlOx layer/the control gate electrode formed from the p-type semiconductor layer), the detrapping characteristic can be enhanced. It has become evident that inhibition of occurrence of the Vfb shift, which would otherwise cause detrapping of electric charges, is possible.

The above test results show that the amount of Vfb shift due to the detrapping phenomenon is greatly diminished by combinations (1), (2) in comparison with the case where only electrons are implanted from the n⁺ electrode to the inverted layer of the p-type substrate.

In the first and second embodiments, only the charge storage layer of high dielectric constant material is used as the gate insulation film. However, in view of an improvement in reliability and an improvement in the effect of preventing fluctuations in threshold value, a tunnel insulation film (tunnel insulation layer) may be interposed between the semiconductor region and the charge storage layer; a blocking insulation film (blocking insulation layer) may be interposed between the charge storage layer and the control gate electrode; or both the tunnel insulation film and the blocking insulation film may be formed. Specific embodiments are provided hereinbelow.

### Third Embodiment

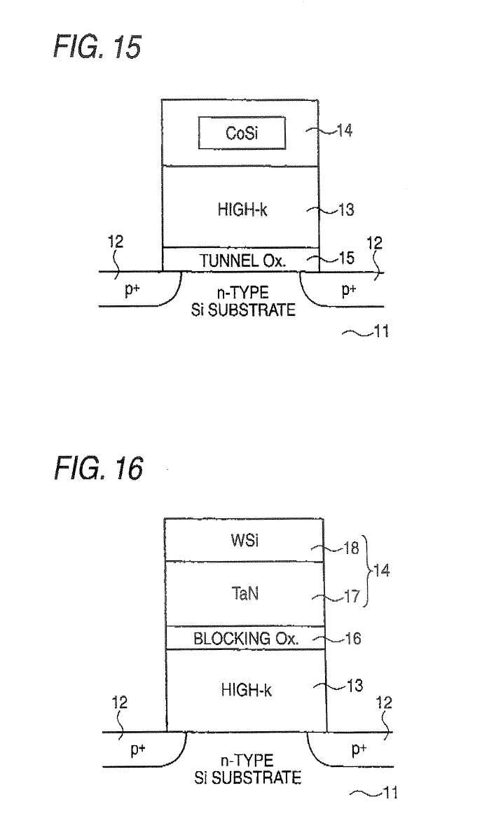

A schematic cross-sectional configuration of a nonvolatile semiconductor memory cell of a third embodiment will be described by reference to FIG. 15. A memory cell of the present embodiment is identical with its counterpart of the first embodiment, except that a tunnel insulation film (tunnel insulation layer) is formed from a silicon oxide film between the n-type silicon substrate and the charge storage layer and that the control gate electrode is composed of a cobalt silicide layer; and corresponds to the memory cell of combination (1).

As shown in FIG. 15, the p⁺-type source-drain regions 12 are formed in the n-type semiconductor region 11 that is formed by doping the silicon substrate with n-type impurities. A tunnel insulation film 15 is formed from a silicon oxide film on the p⁺-type source-drain regions 12. The charge storage layer 13 is formed from HfAlOx on the tunnel insulation film 15. Cobalt silicide is formed on the charge storage layer 13 as the control gate electrode 14.

The thickness of the silicon oxide film forming the tunnel insulation film 15 ranged from 1 nm to 10 nm or thereabouts. The work function of cobalt silicide ranges from about 4.6 eV to 4.7 eV. CoSix can also be formed into a p-type or an n-type, depending on the nature of impurities used for doping A work function can also be controlled by controlling a ratio of Co to Si.

Although in the third embodiment the silicon oxide film is used as the tunnel insulation film, there can be widely used an insulation film material which is lower in dielectric constant than the high-dielectric insulation film used for the charge storage layer, such as SiN, SiON, or Al₂O₃, other than the silicon oxide film.

Processes for manufacturing the memory cell of the third embodiment are as follows.

First, the tunnel oxide film 15 is formed to a thickness of about 1 nm to 5 nm on the surface of the silicon substrate 11 doped with n-type impurities, by thermal oxidation, and the charge storage layer 13 is formed from the HfAlOx layer on the tunnel oxide film as in the case of the first embodiment. Next, the CoSix layer of the control gate electrode 14 is formed by forming Co on the polycrystalline silicon, which has been formed on the HfAlOx layer by CVD, by use of the sputtering method; and converting the polycrystalline silicon layer into CoSix through subsequent heat processes. Subsequently, the substrate is subjected to the same processes as those employed in the first embodiment, whereby a memory cell is formed.

### Fourth Embodiment

A schematic cross-sectional configuration of a nonvolatile semiconductor memory cell of a fourth embodiment will be described by reference to FIG. 16. A memory cell of the present embodiment is identical with its counterpart of the first embodiment, except that a blocking insulation film (blocking insulation layer) is formed from a silicon oxide film between the charge storage layer and the control gate electrode and that the control gate electrode is composed of a tungsten silicide layer; and corresponds to the memory cell of combination (1).

As shown in FIG. 16, the p⁺-type source-drain regions 12 are formed in the n-type semiconductor region 11 that is formed by doping the silicon substrate with n-type impurities. The charge storage layer 13 is formed from HfAlOx on the p⁺-type source-drain regions 12. A blocking insulation film 16 is further formed from a silicon oxide film on the charge storage layer 13. A TaN layer 17 is formed on top of the blocking insulation film 16 as the control gate electrode 14, and a tungsten silicide layer 18 is formed on the TaN layer 17. The thickness of HfAlOx, which is the charge storage layer 13, ranges from 1 nm to 30 nm or thereabouts, and the thickness of the silicon oxide film, which is the blocking insulation film 16, ranges from 1 nm to 10 nm or thereabouts. The work function of TaN is about 4.7 eV. The resistivity of tungsten silicide is smaller than that of TaN.

Although in the present embodiment the silicon oxide film is used as the blocking insulation film, there can be widely used an insulation film material which is larger in barrier height than the high-dielectric insulation film used for the charge storage layer, such as SiN, SiON, or Al₂O₃, other than the silicon oxide film. Thereby, the amount of electrons implanted from the electrode can be controlled, and trapping/detrapping operation from the viewpoint of a tradeoff between the amount of electrons and the amount of holes implanted from the substrate.

Processes for manufacturing the memory cell of the present embodiment are as follows.

First, as in the case of the first embodiment, the charge storage layer 13 is formed on the n-type silicon substrate 11. A silicon oxide film, which is the blocking insulation film 16, is formed on the charge storage layer. Oxidation or radical oxidation of polycrystalline silicon or an ALD method using TDMAS (Trisdimethyl Amino Silane) and ozone as raw materials are employed for forming a silicon oxide film. Next, the TaN layer 17, which is located beneath the control gate electrode 14, is formed on the blocking insulation film 16 by the sputtering method. W is formed on the polycrystalline silicon layer by use of the CVD method using W(CO)₆ as a source gas, and the polycrystalline silicon layer is converted into WSix 18 through subsequent heat processes. Subsequently, a memory cell is obtained through the same processes as those employed in the first embodiment.

### Fifth Embodiment

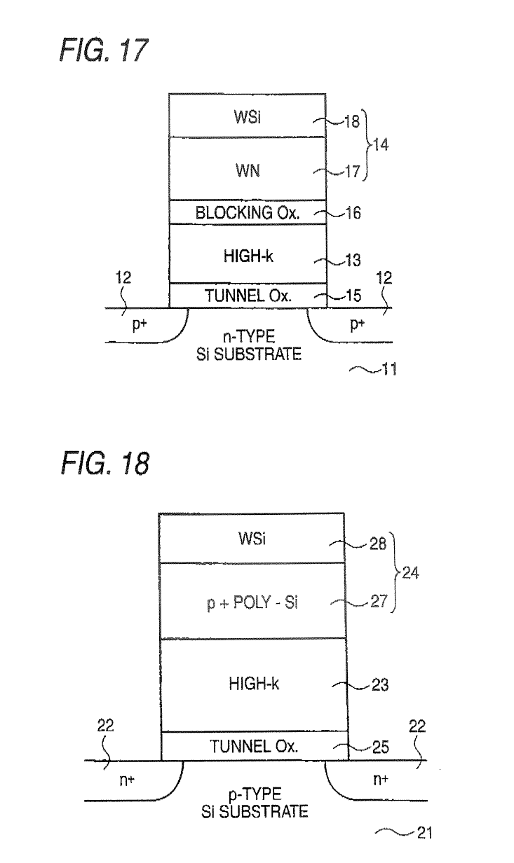

A schematic cross-sectional configuration of a nonvolatile semiconductor memory cell of a fifth embodiment will be described by reference to FIG. 17. A memory cell of the present embodiment is identical with its counterpart of the first embodiment, except that a tunnel insulation film (tunnel insulation layer) is formed from a silicon oxide film between the n-type silicon substrate and the charge storage layer; that a blocking insulation film (blocking insulation layer) is formed from a silicon oxide film between the charge storage layer and the control gate electrode; and that the composition of the control gate electrode is changed. The memory cell corresponds to a memory cell of combination (1).

As shown in FIG. 17, the p⁺-type source-drain regions 12 are formed in the n-type semiconductor region 11 that is formed by doping the silicon substrate with n-type impurities. The tunnel insulation film 15 of a silicon oxide film is formed on the p⁺-type source-drain regions, and the charge storage layer 13 is formed from HfAlOx on the source-drain regions 12. The blocking insulation film 16 is further formed from a silicon oxide film on the charge storage layer 13. A WN (tungsten nitride) layer 17 is formed on top of the blocking insulation film 16 as the control gate electrode 14, and the WSi (tungsten silicide) layer 18 is formed in a stacked manner on the TaN layer 17. In other respects, the memory cell of the present embodiment is identical in structure with the memory cell of the first embodiment.

The thickness of the tunnel insulation film 15 ranges from 1 nm to 10 nm or thereabouts; the thickness of HfAlOx, which is the charge storage layer 13, ranges from 1 nm to 30 nm thereabouts; and the thickness of the silicon oxide film, which is the blocking insulation film 16, ranges from 1 nm to 10 nm or thereabouts.

The work function of WN is about 4.8 to 4.9 eV. The resistivity of WSi is smaller than that of WN.

Although in the present embodiment the silicon oxide film is used as the tunnel insulation film, there can be widely used an insulation film material which is lower in dielectric constant than the high-dielectric insulation film used for the charge storage layer, such as SiN, SiON, or Al₂O₃, other than the silicon oxide film.

Although in the present embodiment the silicon oxide film is used as the blocking insulation film, there can be widely used an insulation film material which is larger in barrier height than the high dielectric constant material used for the charge storage layer, such as SiN or Al₂O₃, other than the silicon oxide film.

Processes for manufacturing the memory cell of the present embodiment are as follows.

First, as in the case of the third embodiment, the tunnel oxide film 15 and the charge storage layer 13 are sequentially formed on the silicon substrate 11 doped with the n-type impurities. Further, as in the case of the fourth embodiment, the blocking insulation film 16 formed from a silicon oxide film is stacked on the HfAlOx layer. Next, the WN layer 17, which is located beneath the control gate electrode 14, is formed on the blocking insulation film 16 by the sputtering method. The tungsten silicide layer 18 is formed by forming a polycrystalline silicon layer on the WN layer 17 through CVD; forming W on the polycrystalline silicon by the CVD method using W(CO)₆ as a source gas; and converting the polycrystalline silicon layer into WSix through subsequent heat processes. Subsequently, a memory cell is obtained through the same processes as those employed in the first embodiment.

### Sixth Embodiment

A schematic cross-sectional configuration of a nonvolatile semiconductor memory cell of a sixth embodiment will be described by reference to FIG. 18. A memory cell of the present embodiment is identical with its counterpart of the second embodiment, except that the tunnel insulation film (tunnel insulation layer) is formed from a silicon oxide film between the p-type silicon substrate and the charge storage layer; and corresponds to the memory cell of combination (2).

As shown in FIG. 18, the n⁺-type source-drain regions 22 are formed in the p-type semiconductor region 21 that is formed by doping the silicon substrate with p-type impurities A tunnel insulation film 25 is formed from a silicon oxide film between the n⁺-type source-drain regions 22 on the p-type semiconductor region 12. The charge storage layer 23 is formed from HfAlOx on the tunnel insulation film 25. A p⁺-type polycrystalline Si layer 27 and a tungsten silicide layer 28 are formed, in this sequence from the charge storage layer 23, on the charge storage layer 23 as the control gate electrode 24.

In other respects, the structure of the memory cell of this embodiment is identical with that of the memory cell of the first embodiment.

The thickness of the tunnel insulation film 27 ranges from 1 nm to 10 nm or thereabouts.

Although in the present embodiment the silicon oxide film is used as the tunnel insulation film, there can be widely used an insulation film material which is lower in dielectric constant than the high-dielectric insulation film used for the charge storage layer, such as SiN, SION, or Al₂O₃, other than the silicon oxide film.

Processes for manufacturing the memory cell of the present embodiment are as follows.

First, the tunnel oxide film 25 is formed to a thickness of about 1 nm to 5 nm on the surface of the silicon substrate 21 doped with p-type impurities, by thermal oxidation. As in the case of the first embodiment, the HfAlOx layer of the charge storage layer 23 is formed. Subsequently, the control gate electrode 24 is formed. First, a phosphor-doped polycrystalline Si layer 25 is deposited at 620° C. by CVD. The tungsten silicide layer (a WSi layer) 27 is formed by forming W by use of the CVD method using polycrystalline W(CO)₆ as a source gas; and converting the polycrystalline silicon layer into Wsix through subsequent heat processes. Subsequently, a memory cell is obtained through the same processes as those employed in the first embodiment.

### Seventh Embodiment

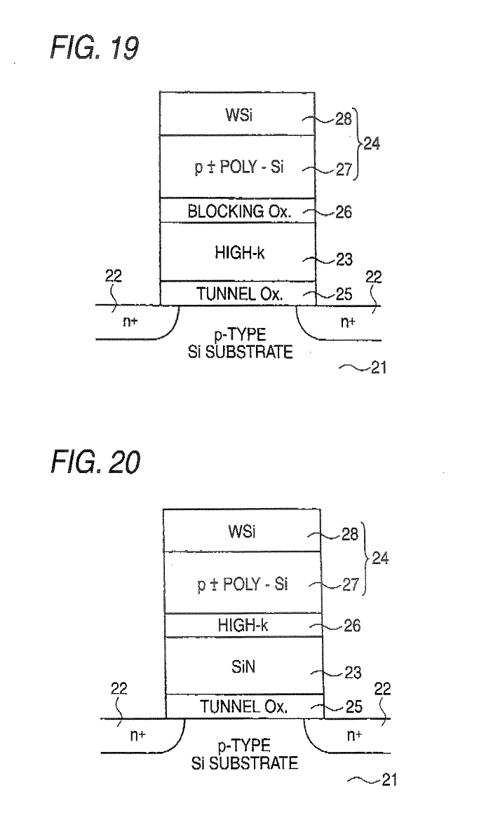

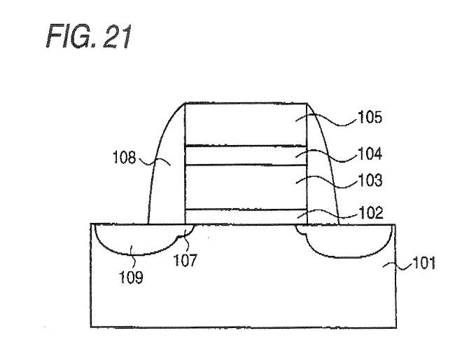

A schematic cross-sectional configuration of a nonvolatile semiconductor memory cell of a seventh embodiment will be described by reference to FIG. 19. A memory cell of the present embodiment is identical with its counterpart of the second embodiment, except that the tunnel insulation film (tunnel insulation layer) is formed from a silicon oxide film between the p-type silicon substrate and the charge storage layer; that a blocking insulation film (blocking insulation layer) is formed between the charge storage layer and the control gate electrode; that the composition of the control gate electrode is changed; and corresponds to the memory cell of combination (2).

As shown in FIG. 19, the n⁺-type source-drain regions 22 are formed in the p-type semiconductor region 21 that is formed by doping the silicon substrate with p-type impurities. The tunnel insulation film 25 is formed between the n⁺-type source-drain regions 22 on the p-type semiconductor area 21. The charge storage layer 23 of HfAlOx is formed on the tunnel insulation film 25. The blocking insulation film 26 of the silicon oxide film is further formed on the charge storage layer 23. The p⁺-type polycrystalline Si layer 27 and the tungsten silicide layer 28 are formed, from the charge storage layer 23, on the blocking insulation film 26 as the control gate electrode 24.

In other respects, the memory cell of the present embodiment is identical in structure with the memory cell of the second embodiment.

The thickness of the tunnel insulation film 15 ranges from 1 nm to 10 nm or thereabouts; the thickness of HfAlOx, which serves as the charge storage layer 23, ranges from 1 nm to 30 nm thereabouts; and the thickness of the silicon oxide film, which serves as the blocking insulation film 26, ranges from 1 nm to 10 nm or thereabouts.

The work function of the p⁺-type polycrystalline silicon is about 5 eV. The resistivity of tungsten silicide is smaller than that of the p⁺-type polycrystalline silicon.

Although in the present embodiment the silicon oxide film is used as the tunnel insulation film, there can be widely used an insulation film material which is lower in dielectric constant than the high-dielectric insulation film used for the charge storage layer, such as SiN, SiON, or Al₂O₃, other than the silicon oxide film.

Although in the present embodiment the silicon oxide film is used as the blocking insulation film, there can be widely used an insulation film material which is larger in barrier height than the high dielectric constant material used for the charge storage layer, such as SiN or Al₂O₃, other than the silicon oxide film.

Processes for manufacturing the memory cell of the present embodiment are as follows.

First, as in the case of the sixth embodiment, the tunnel oxide film 25 is formed on the surface of the silicon substrate 21 doped with the p-type impurities by thermal oxidation. The HfAlOx layer of the charge storage layer 23 is formed. Subsequently, a silicon oxide film, which serves as the blocking insulation film 26, is formed on the charge storage layer. Oxidation or radical oxidation of polycrystalline silicon or an ALD method using TDMAS (Trisdimethyl Amino Silane) and ozone as raw materials is employed for forming a silicon oxide film. Next, the control gate electrode 24 is formed on the blocking insulation film 26 by the same method as that of the sixth embodiment. Subsequently, a memory cell is obtained through the same processes as those employed in the first embodiment.

### Eighth Embodiment

A schematic cross-sectional configuration of a nonvolatile semiconductor memory cell of a eighth embodiment will be described by reference to FIG. 20. A memory cell of the present embodiment is identical with its counterpart of the first embodiment, except that a tunnel insulation film (tunnel insulation layer) is formed from a silicon oxide film between the p-type silicon substrate and the charge storage layer, the charge storage layer is formed from a silicon nitride film, a blocking insulation film (blocking insulation layer) of HfAlOx is provided between the charge storage layer and the control gate electrodes and the material of the gate electrode has been changed; and corresponds to the memory cell of combination (2).

As shown in FIG. 20, the n⁺-type source-drain regions 22 are formed in the p-type semiconductor region 21 that is formed by doping the silicon substrate with p-type impurities. The tunnel insulation film 25 is formed from a silicon oxide film between the n⁺-type source-drain regions 22 on the p-type semiconductor region 21. The charge storage layer 23 is formed from a silicon nitride film on the tunnel insulation film 25. The blocking insulation film 26 of HfAlOx is provided on the charge storage layer 23. The p⁺-type polycrystalline Si layer 27 and the tungsten silicide layer 28 are formed, from the charge storage layer 23, on the blocking insulation film 26 as the control gate electrode 24.

In the present embodiment, as a result of a high dielectric constant material being used for the blocking insulation film of the related-art MONOS memory, there can be prevented occurrence of a leakage current, which would otherwise be caused during writing and deleting operation and would pose a problem in reducing the thickness of the memory; and occurrence of a detrapping phenomenon in the high dielectric constant film, which would otherwise be caused by simultaneous implantation of holes and electrons. Therefore, occurrence of fluctuations in threshold value in a state where the electric charges are retained, which would otherwise be caused by introduction of the high dielectric constant film, can be prevented.

In other respects, the structure of the memory cell of the present embodiment is identical with that of the memory cell of the second embodiment. Introduction of a high dielectric constant material for the charge storage layer in the first through seventh embodiments enables a reduction in electrical thickness of the charge storage layer when compared with the present embodiment. Hence, a greater scale merit can be yielded.

The thickness of the tunnel insulation film 15 ranges from 1 nm to 10 nm or thereabouts; the thickness of the silicon nitride film, which serves as the charge storage layer 23, ranges from 1 nm to 30 nm thereabouts; and the thickness of HfAlOx, which serves as the blocking insulation film 26, ranges from 1 nm to 10 nm or thereabouts.

Although in the present embodiment the silicon oxide film is used as the tunnel insulation film, there can be widely used an insulation film material which is lower in dielectric constant than the high-dielectric insulation film used for the charge storage layer, such as SiON, other than the silicon oxide film.

Although in the present embodiment a silicon nitride film is used as a charge storage layer, a silicon oxynitride film (silicon oxynitride layer) may also be used. The composition of the silicon oxynitride film may be other than a stoichiometric composition.

Although in the present embodiment HfAlOx is used as the blocking insulation film, an oxide, a nitride, or an oxynitride film including at least one or more element selected from Al, Hf, La, Y, Ce, Ti, Zr, and Ta, or a laminated material of the film can also be used as a material of the blocking insulation film.

Processes for manufacturing the memory cell of the present embodiment are as follows.

First, as in the case of the sixth embodiment, the tunnel oxide film 25 is formed on the surface of the silicon substrate 21 doped with the p-type impurities by thermal oxidation. The charge storage layer 23 is formed from a silicon nitride film by CVD. Subsequently, the entire surface of the charge storage layer is oxidized by thermal oxidation, there by forming a silicon oxide film that serves as the blocking insulation film 26. Next, the control gate electrode 24 is formed on the blocking insulation film 26 in the same manner as in the sixth embodiment subsequently, a memory cell is obtained through the same processes as those employed in the first embodiment.

According to the above-embodiments, occurrence of detrapping of electric charges in a state where the electric charges are retained after writing/deleting operation, which would otherwise be caused when a high dielectric constant material is used for a gate insulation film, can be diminished. Consequently, fluctuations in a threshold value of a cell in the state where electric charges are retained after writing/deleting operation can be reduced, and therefore a nonvolatile semiconductor memory device which is superior to a conventional memory device in terms of memory cell performance can be implemented.

According to the above-embodiments, by the action of appropriately controlling the amount of electrons/positive holes implanted into the charge storage layer, detrapping of electric charges, which would otherwise arise in a state where the electric charges are retained, is significantly prevented when a high dielectric constant material is used for a gate insulation film.

According to the embodiments, the related art MONOS memory can be caused to function as a nonvolatile memory device without providing a tunnel insulation film and the blocking insulation film which are provided for preventing detrapping of the electric charges that have once been implanted. However, these films may also be provided in order to reduce a leakage current by improving the state of a boundary surface between another material film, such as a silicon substrate, and a high dielectric constant film, as well as to facilitate control of the amount of electrons/positive holes implanted Elaborate control of the amount of electrons/positive holes implanted into the charge storage layer can be considered to be performed by changing the thickness and material of the films.

Particularly, using an insulation material—which is larger than the charge storage layer in terms of a barrier height and assumes an asymmetrical property of a band offset—for the tunnel insulation film, the blocking insulation film, or both of them enables easy, more precise control of the amount of implanted electrons/positive holes.

For instance, in the respective cases of (1), (2), the ratio of the amount of electric charges implanted by way of the blocking insulation film or the tunnel insulation film can be controlled by use of the film. The greater the thickness of the film, the greater the amount by which implanted electric charges can be reduced.

Methods provided below are conceivable as a method for more elaborately controlling the amount of electrons/positive holes implanted into the charge storage layer.

For instance, in the case of combination (1), n-type Si, a metal-based conductive material, or a p-type semiconductor material including at least one of Si and Ge can be used as a material for use in forming the control gate electrode. The metal-based conductive material includes at least one element selected from Au, Pt, Co, Be, Ni, Rh, Pd, Te, Re, Mo, Al, Hf, Ta, Mn, Zn, Zr, In, Bi, Ru, W, Ir, Er, La, Ti, and Y; silicides, borides, nitrides, or carbides thereof. In this case, the amount of implanted electrons can be controlled by changing the work function of the electrode, As the work function becomes greater, the effect of reducing a leakage current flowing through the high dielectric insulation film is also produced. An increase in the amount of shift in steady threshold voltage due to an increase in the amount of trap can also be expected. The work function is desirably set to a value of 4.7 eV or thereabouts with reference to Mo (about 4.7 eV) and Au (about 5.1 eV), which yielded particularly large effects in the test results. More specifically, using TaC (about 4.8 to 5.0 eV), Ru (about 5.4 eV), WN (4.8 to 4.9 eV), TiN (4.6 to 4.7 eV), TaN (about 4.7 eV), CoSi (4.6 to 4.7 eV), NiSi (about 4.7 eV), or p⁺-type polycrystalline silicon (about 5.1 eV) as a material is desirable.

The amount of electrons/positive holes implanted into the charge storage layer can be more accurately controlled by controlling a write voltage. When an n-type substrate is used, the extent of trapping can be controlled by a change in stress electric field.

What is claimed is:

1. A nonvolatile semiconductor memory device comprising:
a semiconductor layer comprising an n-type semiconductor region;
p-type source-drain regions separated from each other within the n-type semiconductor region;
a charge storage layer provided on the semiconductor layer and between the p-type source-drain regions, the charge storage layer comprising a high dielectric constant material; and
a control gate electrode provided on the charge storage layer and comprising a material selected from n-type Si, a metal-based conductive material, and a p-type semiconductor material including at least one of Si and Ge.

2. The nonvolatile semiconductor memory device according to claim 1, comprising:
a tunnel insulation layer provided on the semiconductor layer and between the p-type source-drain regions, wherein the charge storage layer is provided on the tunnel insulation layer.

3. The nonvolatile semiconductor memory device according to claim 2, comprising;
a blocking insulation layer provided between the control gate electrode and the charge storage layer.

4. The nonvolatile semiconductor memory device according to claim 1, comprising:
a blocking insulation layer provided on the charge storage layer, wherein the control gate electrode is provide on the blocking insulation layer.

5. The nonvolatile semiconductor memory device according to claim 1, wherein a relative dielectric constant of the high dielectric constant material is equal to or more than 15 and is equal to or less than 30.

6. The nonvolatile semiconductor memory device according to claim 1, wherein the high dielectric constant material is at least one of materials selected from an oxide, a nitride, and an oxynitride, the materials including at least one element selected from Al, Hf, La, Y, Ce, Ti, Zr, and Ta.

7. The nonvolatile semiconductor memory device according to claim 1, wherein the metal-based conductive material is at least one of silicides, borides, nitrides, and carbides, or at least one of metal and metal compound, the at least one of silicides, bories, nitrides, carbide and the at least one of metal and metal compound including at least one element selected from Au, Pt, Co, Be, Ni, Rh, Pd, Te, Re, Mo, Al, Hf, Ta, Mn, Zn, Zr, In, Bi, Ru, W. Ir, Er, La, Ti, and Y.

8. The nonvolatile semiconductor memory device according to claim 2, wherein the tunnel insulation layer comprises an insulator material which is larger in barrier height than the high dielectric constant material and which has an asymmetrical band offset.

9. The nonvolatile semiconductor memory device according to claim 3, wherein the blocking insulation layer comprises an insulator material which is larger in barrier height than the high dielectric constant material and which has an asymmetrical band offset.

10. A nonvolatile semiconductor memory device comprising:
a semiconductor layer comprising a p-type semiconductor region
n-type source-drain regions separated from each other within the p-type semiconductor region;
a charge storage layer provided on the semiconductor layer and between the n-type source-drain regions, the charge storage layer comprising high dielectric constant material; and
a control gate electrode provided on the charge storage layer and comprising a material selected from p-type Si, a metal-based conductive material, and a p-type semiconductor material including at least one of Si and Ge.

11. The nonvolatile semiconductor memory device according to claim 10, comprising:
a tunnel insulation layer provided on the semiconductor layer and between the n-type source-drain regions, wherein the charge storage layer is provided on the tunnel insulation layer.

12. The nonvolatile semiconductor memory device according to claim 11, comprising;
a blocking insulation layer provided between the control gate electrode and the charge storage layer.

13. The nonvolatile semiconductor memory device according to claim 10, wherein a relative dielectric constant of the high dielectric constant material is equal to or more than 15 and is equal to or less than 30.

14. The nonvolatile semiconductor memory device according to claim 10, wherein the high dielectric constant material is an oxide, a nitride, and an oxynitride including at least one element selected from Al, Hf, La, Y, Ce, Ti, Zr, and Ta.

15. The nonvolatile semiconductor memory device according to claim 11, wherein the tunnel insulation layer comprises an insulator material which is larger in barrier height than the high dielectric constant material and which has an asymmetrical band offset.

16. The nonvolatile semiconductor memory device according to claim 12, wherein the blocking insulation layer comprises an insulator material which is larger in barrier height than the high dielectric constant material and which has an asymmetrical band offset.

17. The nonvolatile semiconductor memory device according to claim 12, wherein the charge storage layer comprising a silicon nitride layer or a silicon oxynitride layer, and wherein a dielectric constant of the blocking insulation film is higher than a dielectric constant of the charge storage layer.

18. The nonvolatile semiconductor memory device according to claim 13, wherein the charge storage layer comprising a silicon nitride film or a silicon oxynitride layer, and wherein a dielectric constant of the blocking insulation film is higher than a dielectric constant of the charge storage layer.
